(19) United States
(12) Patent Application Publication
(10) Pub. No.: US 2026/0066628 A1
(43) Pub. Date: Mar. 5, 2026

(54) High Voltage Power Line Sensor For Installation And Removal By Aerial Drone

(71) Applicant: Southern States LLC, Hampton, GA (US)

(72) Inventors: Joseph Andreyo, Fayetteville, GA (US); Lawrence B Beagen, Fayetteville, GA (US); Kristofer Lee Moller, Byron, GA (US); Joseph R Rostron, McDonough, GA (US)

(21) Appl. No.: 18/968,871

(22) Filed: Dec. 4, 2024

Related U.S. Application Data
(60) Provisional application No. 63/689,306, filed on Aug. 30, 2024.

(51) Int. Cl. H02G 1/02; B64D 1/08; G01R 15/18; G01R 31/58

(52) U.S. Cl. CPC H02G 1/02; B64D 1/08; G01R 15/181; G01R 31/58

(57) ABSTRACT

A power line sensor is attached and removed from electric power lines more effectively and efficiently than conventional power line sensors. An aerial drone lowers the power line sensor by a connecting rod until a trigger of a mousetrap-like spring clamp comes into contact with the power line. The spring clamp simultaneously attaches the sensor to a power line and releases the connecting rod allowing the aerial drone to fly away with the connecting rod. The spring clamp connection mechanism provides near instantaneous attachment of the sensor to the power line and release of the drone, avoiding the need for the drone to attach to the power line or hover over the installation location for an extended period of time.

### REFERENCE TO RELATED APPLICATIONS

This application claims filing priority to U.S. Provisional Patent Application Ser. No. 63/689,306 filed Aug. 30, 2024, which is incorporated by reference.

### FIELD OF THE INVENTION

The invention pertains to high voltage electric power systems and, more particularly, to a high voltage power line sensor for installation and removal by aerial drone.

### BACKGROUND

High voltage power line sensors hanging from power lines have been in use for decades. In recent years, remotely operated aerial drones have been used to hang the sensors on the power lines. Power line sensors may be installed in remote locations with rugged terrain in windy conditions presenting challenges when installing the sensors with aerial drones. Because the sensor is tightly clamped onto the power line, removing the sensor from the power line can also be challenging. This type of power line sensor system presents a number of additional challenges due to the high voltage, high noise field the drone and sensor operate in, including the need for effective electronic shielding and communication techniques for operating in presence of high voltage and high levels of coronal noise.

U.S. Pat. No. 12,046,887 describes a prior approach to installing power line sensors with aerial drones. This system requires the drone to remain attached to the power line for an extended period of time while the drone attaches the sensor to the power line. The system uses stabilization clamps to temporarily secure the drone to the power line while the sensor is clamped in place.

U.S. Pat. No. 9,932,110 describes another prior approach to installing power line sensors with aerial drones. Again in this system, the drone remains attached to the power line for an extended period of time while the drone connects the sensor to the power line and tests the connection. A need exists for an improved power line sensors that are more easily installed on and removed from electric power lines.

### SUMMARY

The needs described above are met with an electric power line sensor that includers a housing and a spring clamp connection mechanism supported by the housing. The spring clamp includes an upper jaws, a lower jaws, and a trigger. A connecting rod extends between an aerial drone and the upper jaws as the drone lowers the sensor onto a power line. In response to the trigger coming into contact with the power line, the spring clamp simultaneously opens the upper jaws to release the connecting rod and closes the lower jaws to capture the sensor on the power line. The spring clamp connection mechanism provides near instantaneous attachment of the sensor to the power line and release of the drone, avoiding the need for the drone to attach to the power line or hover over the installation location for an extended period of time. This greatly simplifies the sensor and reduces the opportunities for mishap during sensor installation.

The sensor may also include one or more release mechanisms for opening the lower jaws to release the sensor from the power line. A variety of representative release mechanisms for removing the sensor from the power line are disclosed, including, for example, a torsion ring, a scissors vice, a remotely operated electric motorized release, a pull ring, a ball screw, and a tether and a spool.

In another embodiment, the invention includes a power line sensor as described above, a drone for installing the sensor on a power line, and a remote transmission unit (RTU) for relaying power line measurements from the sensor to a remote located control center. A drone controller remotely controls the drone during installation of the sensor. The drone controller receives the power line measurements from the sensor relayed by the RTU for confirmation of proper operation of the sensor during installation of the sensor.

It will be understood that specific embodiments may include a variety of features in different combinations, and that all of the features described in this disclosure, or any particular set of features, need not be included in any particular embodiments. The specific techniques and structures for implementing particular embodiments of the invention and accomplishing the associated advantages will become apparent from the following detailed description of the embodiments and the appended drawings and claims.

### BRIEF DESCRIPTION OF THE FIGURES

The numerous advantages of the invention may be better understood with reference to the accompanying figures in which:

FIGS. 1A-1C are conceptual illustrations of high-voltage sensor systems.

FIG. 2 is a functional block diagram of an electric power management system utilizing a power line sensor.

FIGS. 3A-3C are perspective views of a power line sensor.

FIGS. 4A-4B are front views of the power line sensor.

FIG. 5 is a conceptual illustration of instrumentation in a power line sensor.

FIG. 6 is an exploded conceptual illustration of instrumentation in a power line sensor.

FIGS. 7A-7B are conceptual illustrations of release mechanisms for a power line sensor.

FIGS. 8A-8B are conceptual illustrations of another alternative release mechanisms for a power line sensor.

FIG. 9 is a conceptual illustration of a shielding system for a power line sensor.

FIG. 10 is a conceptual illustration of corona rings for a power line sensor.

FIGS. 11A-11C are conceptual illustrations of a saddle shaped corona shield for a power line sensor.

FIG. 12 is a conceptual illustration of a release mechanism for a power line sensor.

FIG. 13 is a conceptual illustration of an alternative release mechanism for a power line sensor.

FIGS. 14A-14B are conceptual illustrations of voltage sensor deployment by a power line sensor.

FIG. 15 is a conceptual illustration of a current transformer iron core for a power line sensor.

FIGS. 16A-16C are conceptual illustrations showing optional features of the power line sensor.

FIGS. 17A-17B illustrate operation of a spring clamp of the power line sensor.

### DETAILED DESCRIPTION OF REPRESENTATIVE EMBODIMENTS

The invention is directed to power line sensors attached and removed from electric power lines more effectively and efficiently than conventional power line sensors. A representative embodiment uses an aerial drone to lower a power line sensor by a connecting rod onto the power line. The drone lowers the sensor until the trigger of a mousetrap-like spring clamp comes into contact with the power line. This causes the spring clamp to trip, simultaneously attaching the sensor to the power line and releasing the connecting rod and thus releasing the aerial drone to fly away with the connecting rod. The spring clamp connection mechanism produces the advantage of near instantaneous attachment of the sensor to the power line and release of the drone, greatly simplifying the installation process and reducing chances for mishap during sensor installation.

Conventional high voltage sensor installation and removal techniques are expensive and require either personnel risk or large and expensive equipment for very high voltages. There is a need to install the sensors on electric power transmission and distribution lines at high voltage while the power line remains energized. At some point after the sensor has been attached to the power line, the drone or another device must perform some action to release the sensor. Preferably, the sensor can be released from a drone or a remote location without a lineman having to physically touch the sensor or power line. Improved techniques and systems for drone-based sensor placement and removal will facilitate system-wide installation of power line sensors making the power system more sustainable and reliable while improving the cost and safety risks involved.

The representative embodiments include a spring clamp connection mechanism that simultaneously connects the sensor to the power line while releasing the drone, which avoids the need for the drone to contact the power line or hover over the installation location for an extended period of time. The aerial drone uses an insulated connecting rod to lower the sensor onto the power line. The spring clamp is tripped when a spring clamp trigger comes into contact with the power line. Tripping the spring clamp closes a lower jaws to attach the sensor to the power line, while simultaneously opening an upper jaws to release the connecting rod. Clamping the sensor to the power line and releasing drone simultaneously provides the advantage of near instantaneous attachment of the sensor and release of the drone, avoiding the need for the drone to attach to the power line or hover over the installation location for an extended period of time. The spring clamp also allows the sensor, rather than the drone, to fasten the sensor to the power line without requiring the drone to touch the power line or hover over the installation location for an extended period of time. This simplifies the connection mechanism and the drone installation process compared to prior sensors installed by aerial drones.

A variety of representative release mechanisms for removing the sensor from the power line are disclosed, including a torsion ring, a scissors vice, a remotely operated electric motorized release, a pull ring, a ball screw, and a tether and a spool. In certain embodiments, a torsion or pull ring on top or bottom of the sensor serve as attachment and release points for a “hot-stick” used to rotate or pull the clamp from the power line while the power line remains energized. In other examples, the aerial drone operates the release mechanism to remove the sensor from the power line.

Certain embodiments may also include a drone controller for operating the drone either locally or remotely, for example from a central Supervisory Data Acquisition and Control (SCADA) central controller or another convenient location. The system may also include a remote transmission unit (RTU) for relaying power line data from the power line sensor to a remote control center. In this case, the drone controller communicates with both the drone and the RTU to test and confirm proper operation of the sensor once installed on the power line. In certain embodiments, the remote control center is operated by the same electric utility or other entity that operates the monitored power line. In most cases, the sensor and drone system, which is referred to in the singular, is part of a wider, system-wide network of electric transmission and distribution power lines with power line sensors installed and in some embodiments, installed and removed from a remote control center, typically a SCADA utility operations center.

The drone uses an insulated connecting rod to lower the sensor until a trigger in the sensor contacts the power line, which trips a spring clamp toggle mechanism to release a latch to close a spring-loaded clamp of the sensor as the sensor is lowered onto the power line. The power line itself may contact the trigger that causes the spring clamp to snap closed on the power line. In some embodiments, the drone removes the connecting rod after the spring clamp has been tripped, and in other embodiments the connecting rod remains connected to the sensor, where it serves one or more additional functions including: a corona ring, a torsion ring for releasing the clamp, a pull ring for releasing the clamp, the primary antenna of the sensor, and an auxiliary antenna for the sensor.

Several additional representative release mechanisms are disclosed for removing the sensor from the power line including: a motorized release mechanism that drops the sensor from the power line into a drone-based or ground-based recovery net; a manually-operated torsion ring operated from the ground with a “hot stick”; a motor-operated scissors vice mechanism operated from the drone; a motor-operated torsion ring operated from the drone; a pull ring operated by the drone typically in a fly-by sensor removal operation; a manually-operated torsion ring operated from the ground, typically from a bucket truck on the ground under the power line; a pull ring operated from the ground, typically from a bucket truck on the ground under the power line; a motor-operated release operated from the ground or a remote control center that drops the sensor into a net. Most embodiments include at least two release mechanisms, such as an upper torsion release ring operated from the drone, and lower torsion release ring operated with a “hot-stick” from a bucket truck. In a representative embodiment, the upper release, which is spaced apart from the power line into the high voltage field, also serves as a corona ring. Additional unique shielding prevents corona and other stray EMF from interfering with the operation of the sensors.

System-wide power line sensors communicate power line data to external components located at the sensor location, such as a visual indicator (alarm), at a switch controller for operating the monitored power line. The power line sensor communicates with a central controller that performs a variety of services utilizing the power line data supplied by a system-wide set of power line sensors. The power line sensor may communicate directly with the remote control system or indirectly by way of a remote transmission unit (RTU) positioned at the power line sensor location. The services provided by the central controller include, for example. real-time control of power line switches, voltage regulators, capacitor banks, distributed generators and other power supply, transmission, and distribution equipment.

A representative embodiment of the invention includes a high voltage sensor system including a power line sensor and an aerial drone for installing and removing the sensor from a high voltage electric power line. As an option, the system may also include a drone controller for operating the drone, which may be implemented as a mobile phone app. Alternatively the drone may be controlled remotely, for example from a SCADA control center with one or drone-based cameras and a local surveillance camera in a convenient location, such as a local remote transmission unit (RTU). As another option, the system may also include the RTU mentioned above for relaying power line data from the power line sensor to a remote control center that operates the monitored power line and, in most cases, a wider electric transmission and distribution system. In this case, the drone controller communicates with both the drone and the RTU to test and confirm proper operation of the sensor once installed on the power line.

In a representative embodiment of the sensor, the drone utilizes a non-conductive connecting rod to place the power line sensor on the power line to be monitored. This connecting rod trips the trigger of a connection mechanism when the trigger comes into contact with the power line that simultaneously attaches the sensor to the power line and releases the drone from the sensor. A spring clamp is the preferred connection mechanism due to its simplicity, low weight, low cost, and ease of use and ability to firmly grasp the power line. Other types of connection mechanisms include push-pull insertion, magnetic, rotation (e.g. manual or drone motor), or electro-mechanical (e.g. solenoid) mechanism. Clamping the sensor onto the power line can be done manually, or radio controlled. When the sensor is lowered onto the power line, the spring clamp trigger comes into contact with the power line causing the spring clamp to trip. This simultaneously opens the upper jaws to release the connecting rod, and closes the lower jaws to clamp the sensor onto the power line, where the sensor is safely retained until removed.

The trigger of the spring clamp is tripped when the drone brings the sensor into contact with the power line. This causes the spring clamp to snap onto the power line conductor like a mousetrap and simultaneously release the connecting rod allowing the drone to fly away. The drone does not need to attach to the power line or pause over the installation location for an extending period of time greatly simplifying the sensor installation process compared to prior systems. Once the power line sensor is safely in the proper position, it can be released by a drone motor radio signal that triggers the release mechanism. A variety of release mechanisms and other features of the sensor system are described below.

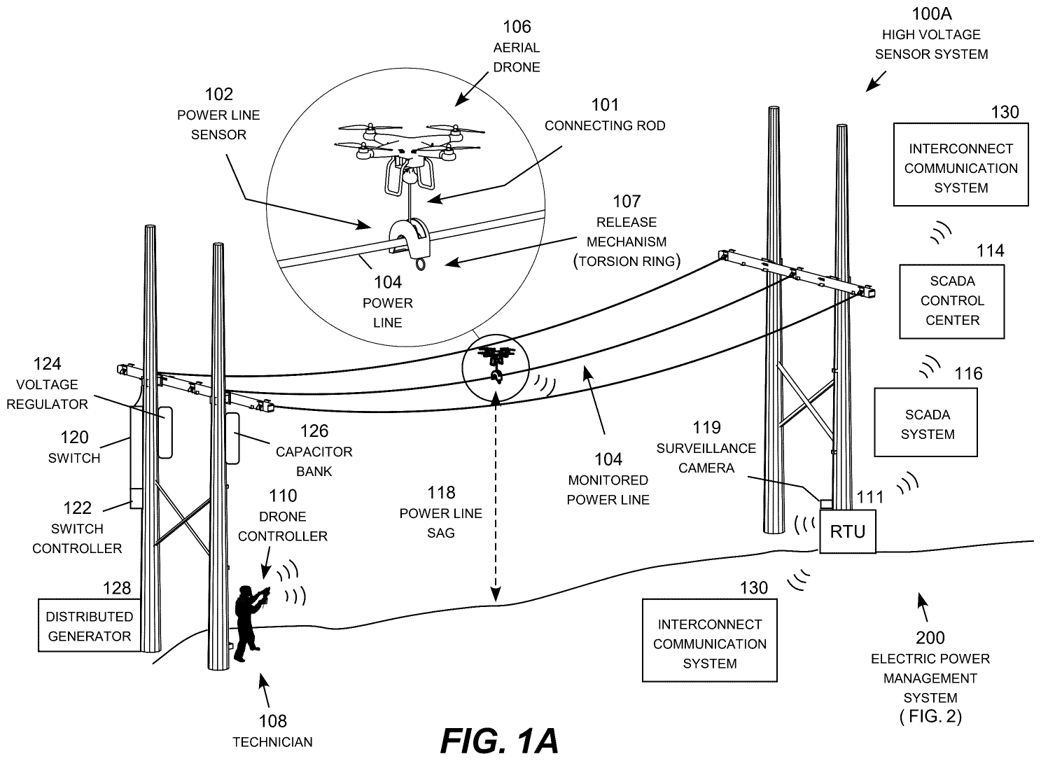

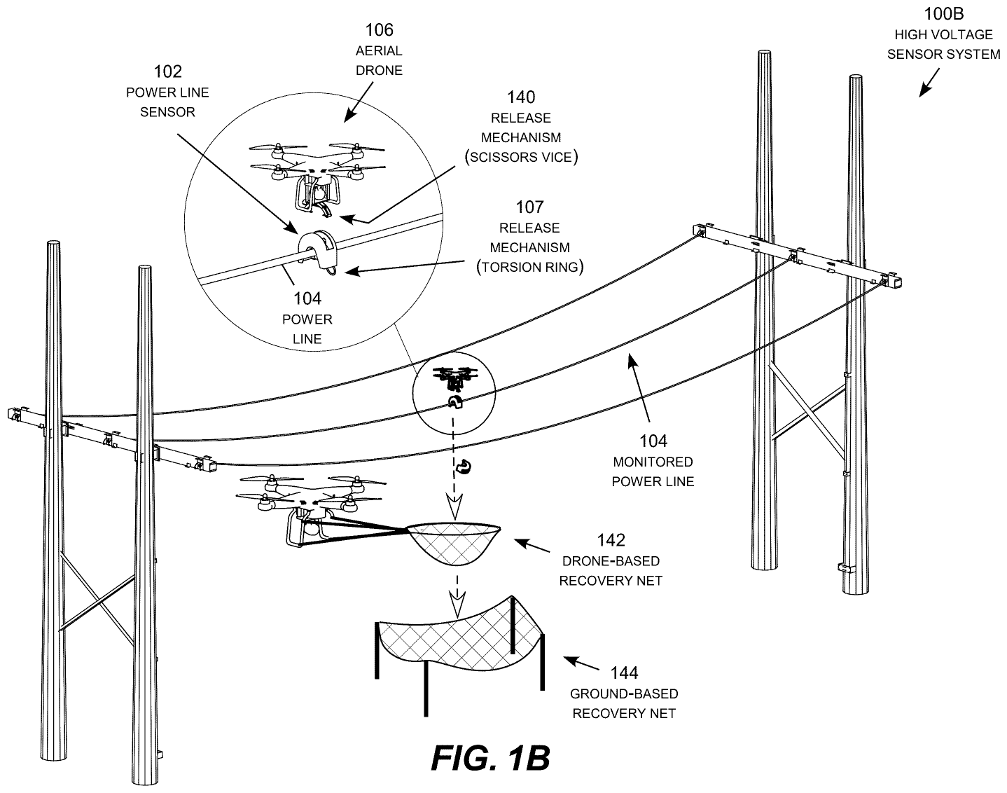

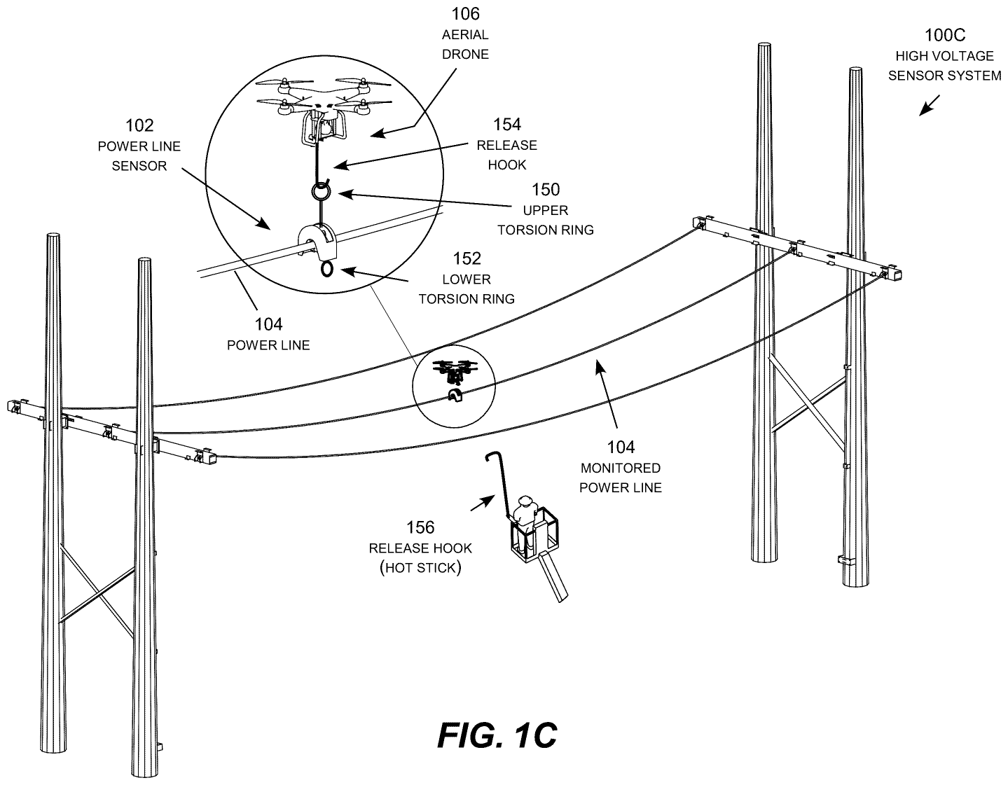

FIG. 1A is a conceptual illustration of a representative high voltage sensor system 100A for installing a power line sensor 102 on a high voltage electric transmission or distribution line conductor 104 (also referred to as the monitored power line). An aerial drone 106 is used to install, and in some embodiments may also be used to remove, the sensor 102 from the monitored power line 104. The sensor 102 includes a connecting rod 101, which the drone uses to lower the sensor onto the power line. The sensor 102 includes a connection mechanism, such as a spring clamp, for simultaneously attaching the sensor to the power line and releasing the connecting rod. The sensor 102 includes one or more, typically at least two, release mechanisms for removing the sensor from the power line. In this embodiment, a torsion ring 107 is illustrated as representative release mechanism. The torsion ring, which is connected to the clamp by a torsion cable linkage, is rotated manually or by a motor to open the spring clamp to release the sensor 102 from the power line 104.

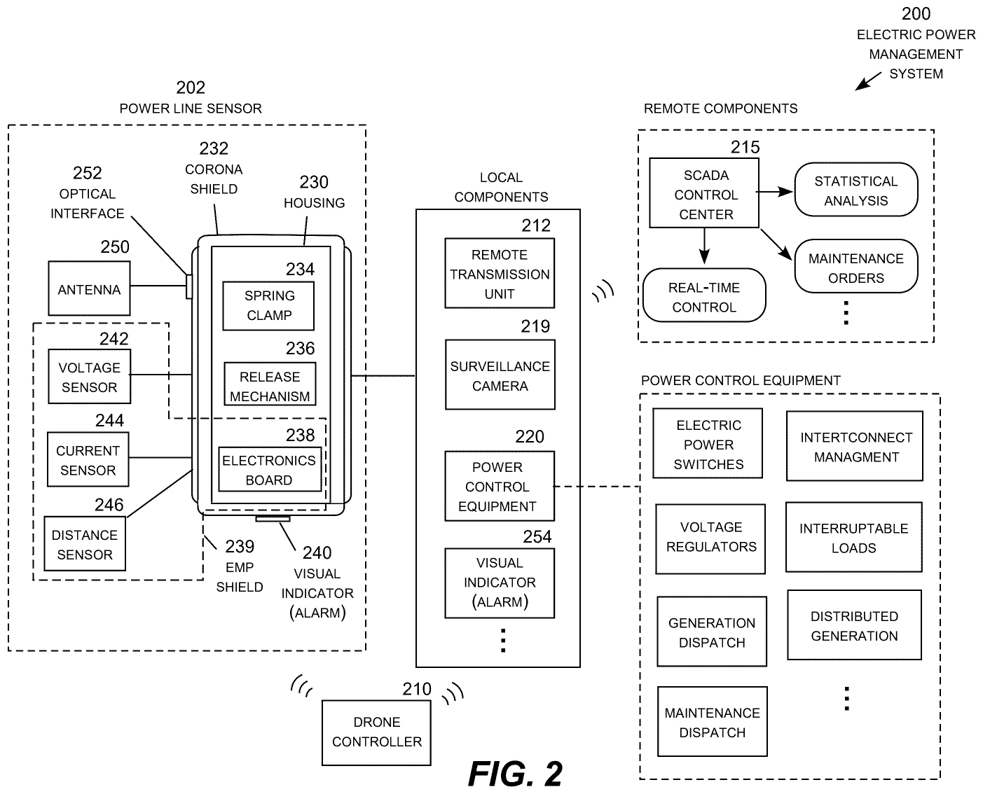

A technician may use a drone controller 110 to operate the drone 106 when installing, and in some embodiments when removing, the sensor 102 from the monitored power line 104. In this embodiment, the sensor 102 transmits the power line data to a remote transmission unit (RTU) 111 located nearby, typically at the base of the pole or other power line support structure, during normal operations. The RTU 111, in turn, transmits the power line data to a central controller 114, typically as part of a supervisory control and data acquisition (SCADA) system 116 utilized by the operator of the monitored power line 104. The representative sensor 102 installed on the monitored power line 104 is typical of a system-wide set of sensor and power lines operated by an electric utility as part of an electric power management system 200, described in greater detail with reference to FIG. 2.

In the high voltage sensor system 100A, the drone controller 110 communicates with the sensor 102, the drone 106, and the RTU 111 to test and ensure that the sensor is operating properly once installed on the power line. One function of the sensor may be to measure the power line sag 118 using a lidar or other measuring device. The local equipment may also include a surveillance camera 119, for example as part of the RTU 111, for visually monitoring the sensor 102 including a visual indicator, such as an LED, on the housing of the sensor. The technician calibrates the sensor 102 to ensure that the power line sag 118 measured by the sensor 102 matches an independent measurement taken at the power line location. The technician similarly calibrates or verifies other power line parameters measured by the sensor 102, such as the line current, voltage, power factor, conductor temperature, ambient temperature, GPS location, time of day, and so forth. The sensor 102 may also utilize a burst communication technique to avoid corona interference, as described in U.S. Pat. No. 9,581,624, which is incorporated by reference. The power line data from the sensor 102 may be used to operate a power line switch 120 by way of a switch controller 122, a voltage regulator 124, capacitor bank 126, a distributed generator 128, interconnect communication system 130 controlling electric interties and other electric power generation, transmission, distribution or conditioning equipment.

FIG. 1B is a conceptual illustration of another representative high voltage sensor system 100B, which includes a different type of release mechanism. In this option, a scissors vice 140 carried by the aerial drone 106 used to remove the sensor 102 from the power line. As another option, the sensor may be released by a release mechanism onboard the sensor, such as a remotely controlled ball screw device, releases the sensor to fall into a drone-based recovery net 142 or ground-based recovery net 144.

FIG. 1C shows another alternative high voltage sensor system 100C, which includes two release mechanisms, an upper torsion ring 150 and a lower torsion ring 152. A release hook 154 carried by the aerial drone 106 may be used to rotate the upper torsion ring 150 to release the sensor from the power line. In addition, a technician carrying a “hot stick” release hook 156 may rotating the lower torsion ring 152 to release the sensor 102 from the power line 104.

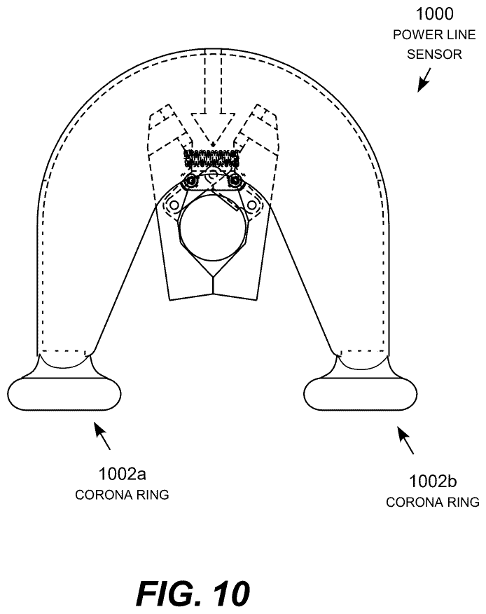

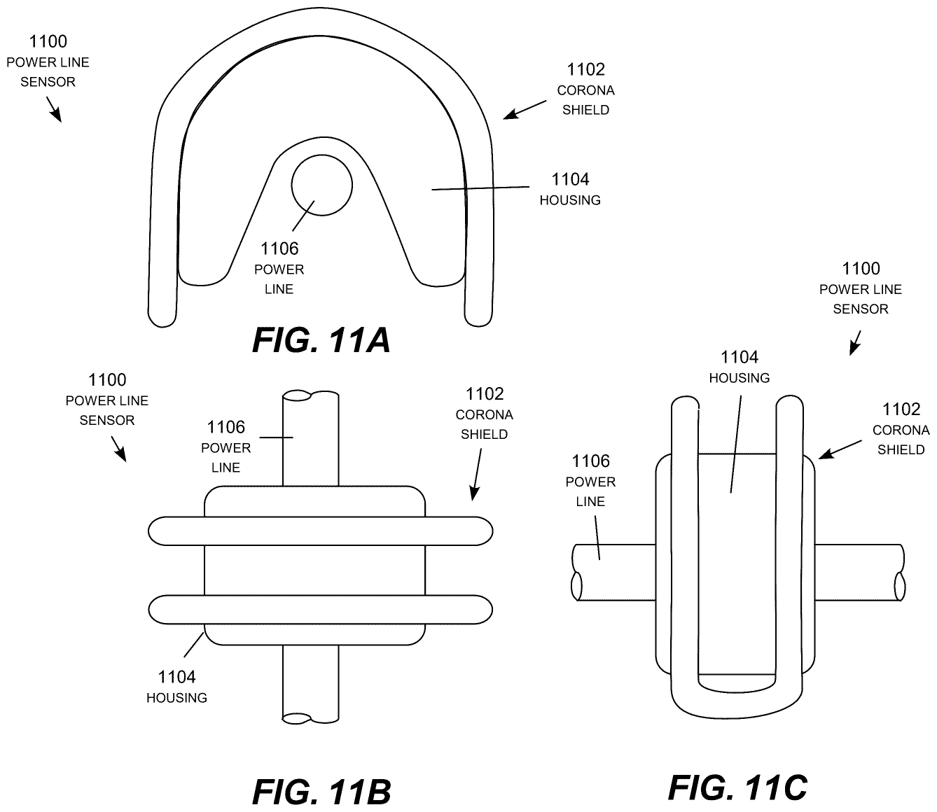

FIG. 2 is a functional block diagram of a high voltage sensor 202, which is part of the larger, system-wide electric power management system 200. The power line sensor 202 includes a housing 230 protected by a corona shield 232. The housing 230 may be fabricated from polyester, polycarbonate or another suitable plastic material. In some embodiments, the housing may be fabricated from metal as part of the corona shielding. In this example, a plastic housing 230 carries a metal corona shield 232, representative examples of which are described below with reference to FIGS. 10 and 11A-11B. The housing 230 encloses, supports or interfaces with a spring clamp 234, one or more release mechanisms 236, an electronics board 238 and an optional visual indicator 240, such as a LED visible from the ground and the surveillance camera 219. The housing 230 encloses, supports or interfaces with a voltage sensor 242 (e.g., capacitive electric field sensor), a current sensor 244 (e.g., current sensor (CT) formed by the spring clamp or Rogowski coil, a distance sensor 246 (e.g., lidar), and an antenna 250.

The electronics board 238, voltage sensor 242, a current sensor 244 and distance sensor 146 may be enclosed in an electromagnetic pulse (EMP) shield 239 (also referred to as a Faraday cage) allowing the sensor to remain operative after a significant EMP event. The antenna 250 may be located outside the Faraday cage with an optical interface 252 providing an EMP-proof communication interface. If the EMP pulse disables the antenna 250, the spring clamp 234, release mechanism 236, or another device may be used as an auxiliary antenna in a post-EMP situation. While the transmission range of the auxiliary antenna may be reduced, the EMP hardened sensor 202 will still be operational with one or more functioning communication links after the EMP pulse.

As noted previously, the sensor 202 typically operates in concert with local components represented by the drone controller 210, remote transmission unit (RTU) 212, surveillance camera 219 and power control equipment 220. The local components may also include a visual indicator (alarm) 254, for example as part of the RTU 212. The sensor 102 and/or the RTU 212 communicate with remote components 214, typically by way of the utility SCADA system 116. The SCADA controller center provides a variety of services using the power line data provided by the sensor 102, such as real-time control of electric power equipment, represented at least in part by the local components 120-130 shown n FIG. 1.

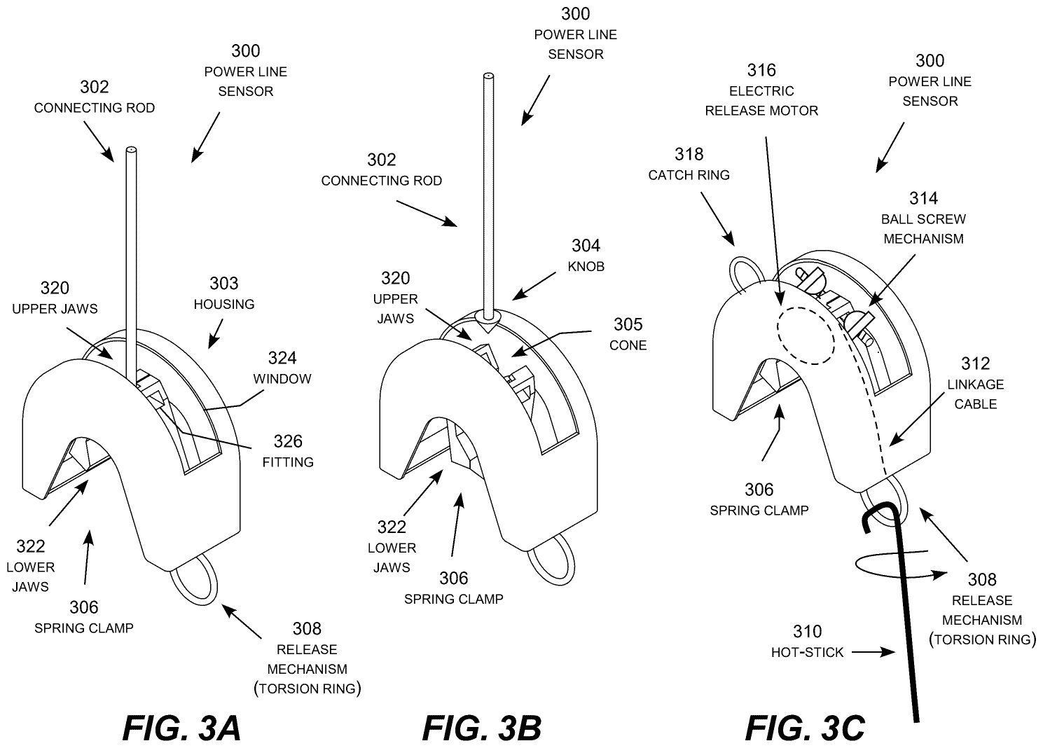

FIGS. 3A-3C are perspective views of a representative power line sensor 300. This embodiment includes an insulated connecting rod 302 with a knob 304 (also referred to as a key) on the end releasably captured by the sensor. The connecting rod 302 is fabricated from a non-conducting material, such as nylon or polycarbonate, to avoid corona generation which could cause a flashover or other electromagnetic disturbance damaging or destabilizing the drone.

The sensor 300 includes an arched housing 303 that supports a spring clamp 306, which includes an upper jaws 320 and a lower jaws 322. The housing 303 includes a window 324 allowing the connecting rod 302 and an external release mechanism to access the upper jaws 324. The upper jaws 320 also defines a pair of fittings for closing the upper jaws with an external release mechanism (only one fitting 326 is visible and in FIG. 3A).

The upper jaws 305 forms a cone for receiving the knob 304. When the spring clamp 306 is in an open position (i.e., lower jaws 322 open) shown in FIG. 3A, the lower jaws 322 is open to release the sensor from the power line, while the upper jaws 320 is closed to grasp the knob 304. When the spring clamp 306 is in a closed position (i.e., lower jaws 322 closed) shown in FIG. 3B, the lower jaws 322 is closed to attach the sensor to a power line, while the upper jaws 320 is open to release the knob 304. When the drone lowers the sensor 300 onto the power line, the power line comes into contact with a trigger, such as a release button or lever. This triggers the spring clamp 306 to snap from the open position shown in FIG. 3A to the closed position shown in FIG. 3B, which simultaneously attaches the lower jaws 322 to the power line while releasing the connecting rod 302 allowing the drone to fly away with connecting rod 302.

The sensor 300 may include multiple types of release mechanisms for flexibility to meet the needs of different applications and removal circumstances. As a first example release mechanism, this embodiment includes a torsion ring 308 located on the bottom portion of the housing 303. As shown in FIG. 3C, the torsion ring 308 is rotated by a hot-stick 310, typically from a bucket truck, to crank open the spring clamp 306. A sheathed cable 312 similar to an odometer cable allows rotation of the lower torsion ring 308 to open the spring clamp. In this embodiment by rotating a ball screw 314 with captured nuts linked to the clamp arms causing lateral translation of the clamp arms toward each other in response to rotation of the ball screw.

The sensor 300 may include multiple types of release mechanisms for flexibility to meet the needs of different applications and removal circumstances. As another release option, the sensor 300 may include an electric release motor 316 for spinning the ball screw or another mechanism (e.g., scissors mechanism) to open the clamp 306. The electric release motor 316 may be remote controlled by the drone, which attaches a lanyard to the drone or is configured and positioned to catch the sensor as it falls from the power line. For example, the drone may attach a lanyard or pass a hook through the catch ring 318 positioned on the housing of the sensor. The electric release motor 316 may be remotely controlled by the drone, drone controller-operated by a ground-based technician, the RTU operated by the SCADA control center, or other convenient control location. The sensor, once released, is recovered by a lanyard or falls into a drone-based net, a ground-based net, or another suitable catching device. In some locations, such as transmission lines with restricted rights of way, the sensor may be simply dropped into the powerline right-of-way for later retrieval.

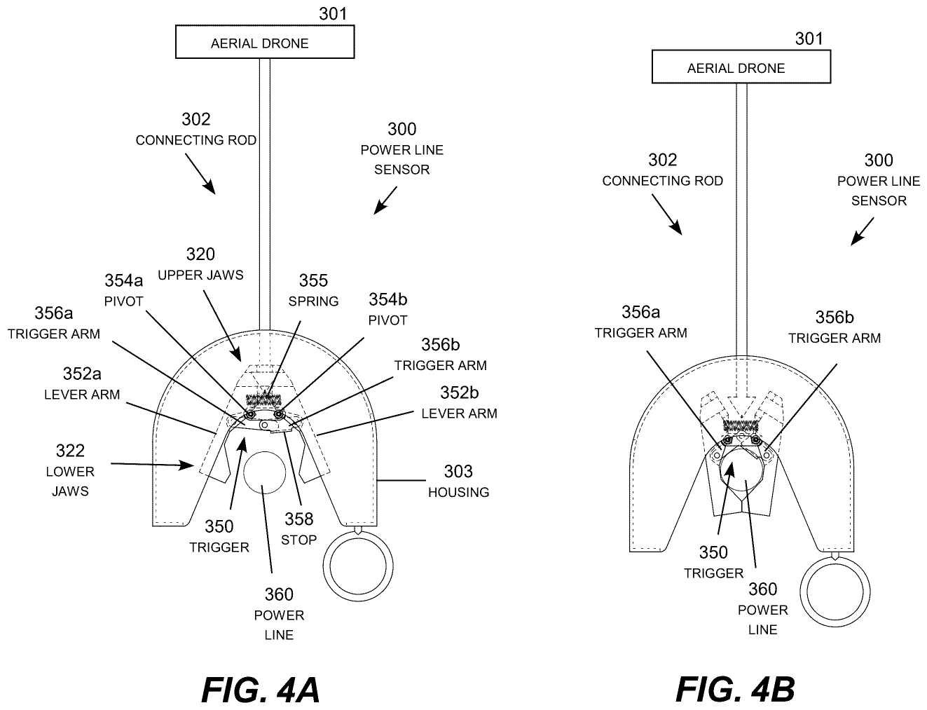

FIGS. 4A-4B are additional conceptual illustrations of the representative power line sensor 300 illustrating an example trigger 350. The upper jaws 320 and lower jaws 322 are formed by a pair of lever arms 352a and 352b. The lever arm 352a is supported by the housing 303 at a pair of pivot points represented by the enumerated pivot 354a. Similarly, the lever arm 352b is supported by the housing 303 at a pair of pivot points represented by the pivot 354b. The trigger is formed by a pair of trigger arms 356a and 356b pivotally connected to the lever arm 352a and 352b, respectively. In this example, the trigger arm 356b includes a stop 358 that limits the rotation of the trigger arms, thus latching the trigger 350 in the open position shown in FIG. 4A.

A spring 355 biases the upper jaws 320 toward open. To load the spring clamp, the lower jaws 322 is manually opened until the trigger arms 356a and 365b latch, as shown in FIG. 4A. When the aerial drone 301 lowers the sensor 300 until the trigger 350 comes into contact with the power line 360, the power line pushes the trigger arms 356a and 365b upward to release the latch, as shown in FIG. 4B, to simultaneously open the upper jaws 320 and close the lower jaws 322. This simultaneously attaches the sensor 300 to the power line 360 and releases the connecting rod 302 to allow the aerial drone to fly away with the connecting rod. The spring clamp connection mechanism produces the advantage of near instantaneous attachment of the sensor and release of the drone, avoiding the need for the drone to attach to the power line or hover over the installation location for an extended period of time. This greatly simplifies the sensor and reduces the opportunities for mishap during sensor installation.

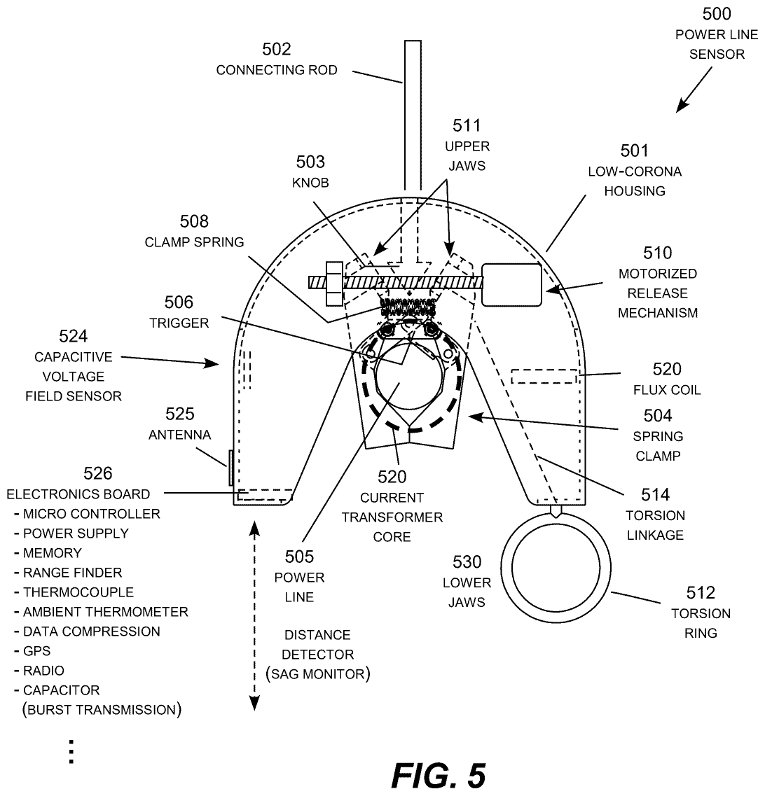

FIG. 5 is a conceptual diagram illustrating instrumentation of a representative power line sensor 500 including a low-corona housing 501. The knob 503 on the insulated connecting rod 502 triggers the spring clamp 504 when the drone causes the trigger 506 to come in contact with the power line 505 releasing the clamp spring 508. The spring clamp 504 is compressed or tensioned and latched prior to installation of the sensor, for example by manually forcing the clamp open, until it latches in the open position. The trigger trips the latch to snap the spring clamp 504 closed on the power line 505. This particular example includes two release mechanisms, the remotely controlled motorized release mechanism 510 that translates the upper jaws 511 toward each other and the lower jaws 513 away from each other to open the spring clamp 504. The sensor also includes and a torsion ring 512 with linkage cable 514. As an option, the system may utilize one or more mechanical release mechanisms (e.g., scissors vice and torsion ring) with motorized release mechanism as a back up or alternative embodiment.

With respect to instrumentation, this embodiment the lower jaws 530 of the spring clamp 504 forms a closed-ring current transformer (CT) core 520 the power line 505 when the spring clamp 504 is in the closed position. Alternatively, a Rogowski coil current sensor may be wrapped around power line. Voltage measurement can be provided in a variety of ways, such as a flux coil 522 positioned radially to the power line 505 in its magnetic field. Another option includes a capacitive voltage sensor 524, such as metallic plates or PC board layers, radially spaced apart in the voltage field. The sensor 500 also includes an antenna 525 in communication with an electronics board 526 including suitable components, such as a microcontroller, power supply, memory, range finder (distance sensor), thermocouple for measuring temperature of the power line, thermometer for measuring ambient temperature, data compression software, GPS, radio, and capacitor for corona-avoidance burst transmission during current zero-crossing intervals. The electronics board utilized electric power harvested from the power line by the previously described current and/or voltage sensors and may include a back-up rechargeable battery, capacitor bank or one or more super-capacitors. The power supply conditions and regulates the power, for example providing a few millivolts and milliamps sufficient to run the electronic and local transmissions to an RTU. For local transmissions, the sensor may use Bluetooth or other high-bandwidth communication channels in the single-digit gigahertz range.

In addition, this configuration may be alternatively configured to supply on the order of 5 Volts DC and 500 milliamps for longer range transmissions bypassing or obviating the need for the RTU. With this power level, adequate shielding and corona-avoidance burst transmissions, the power line sensor 500 can transmit power line data commensurate with cellular telephones, for example on the order of 10-15 miles. For longer transmissions, the sensor may use lower-bandwidth communication channels in the 300-600 MHz range. In this case, the sensors may be configured to operate as a mesh communication network.

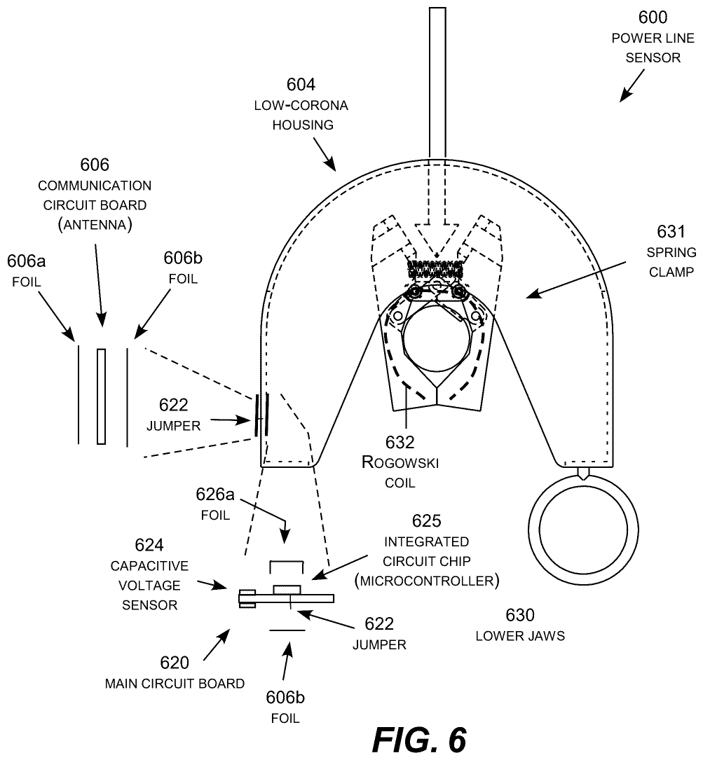

FIG. 6 is a conceptual diagram illustrating additional instrumentation and shielding for a representative power line sensor 600. The embodiment includes a communication circuit board 602 including the primary antenna for the sensor. The communication circuit board 602 is disposed on the outside a low-corona housing 604. Metal foil layers 606a and 606b cover all or a [portion of the communication circuit board 602 including, if desired all or a portion of the antenna. The sensor also includes a main circuit board 620 on the inside of the housing 504 substantially parallel to and opposing the communication circuit board 602 with a jumper 622 electrically connecting the circuit boards 606 and 620. The main circuit board 620 includes the components of the electronics board 526 described previously. In addition, the main circuit board 620 include a capacitive voltage field sensor configured as metallic circuit board traces or PC board layers spaced apart by a dielectric PC board layer. The main circuit board 620 also includes a foil clamshell and foil 626a and 626b shield layers covering opposing sides of the integrated circuit chip 625 (microcontroller). In this embodiment, the lower jaws 630 of the spring clamp 631 wraps a Rogowski coil 632 current sensor around the power line when the spring clamp is in the closed position.

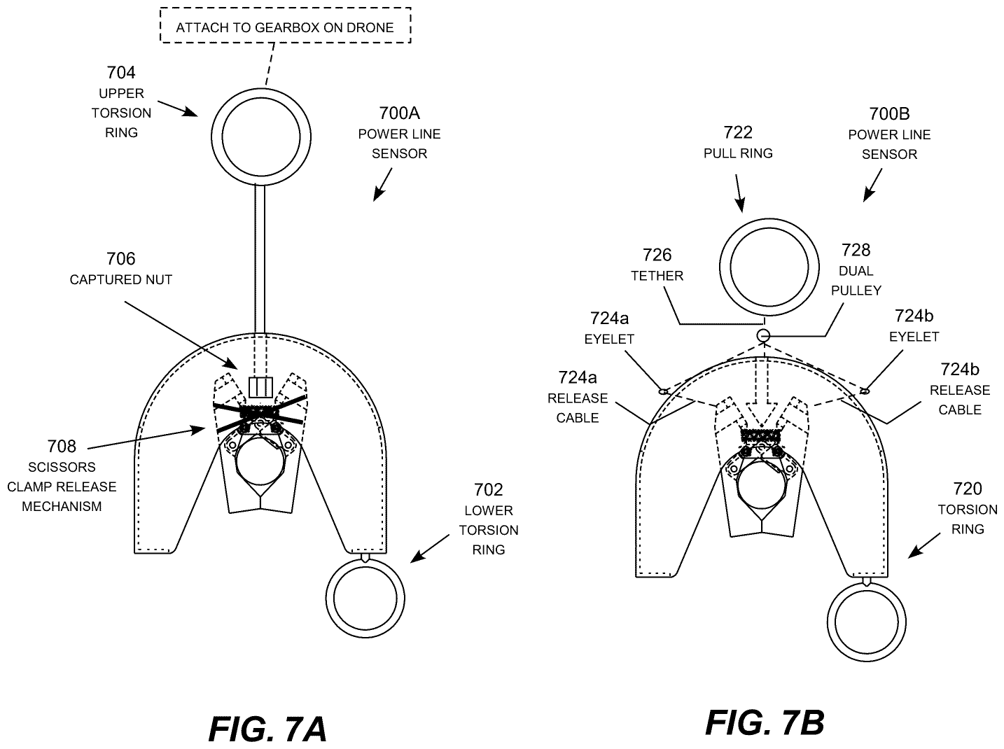

FIGS. 7A-7B illustrate alternative sensors 700A and 700B with alternative types of release mechanisms. Sensor 700A shown n FIG. 7A includes a lower torsion ring 702 and an upper torsion ring 704 that includes a captured nut for operating the clamp release mechanism. Alternatively, a remotely-operated motor may be used to operate the scissors type clamp release mechanism. Sensor 700B shown n FIG. 7B includes a lower torsion ring 722 and an upper pull ring 722 operated a pair of release cables or mechanical links 724a and 724b coupled vie eyelets 725a and 725b. respectively, to the pull ring by a tether 726 via a captured dual pulley 728 for releasing the clamp. Referring to FIG. 7A and FIG. 1C, an alternative high voltage sensor system 700A utilizes an aerial drone 802 with release hook 113 extending from a gearbox on the drone 106 to rotating the upper torsion ring 704 to remove the sensor 700A from the power line. In addition, a technician can use a hot-stick to rotate the lower torsion ring 702 to remove the sensor from the power line. Referring to FIG. 7B, the release hook or other fly-by recovery hook is used to lift the pull ring 722 to remove the sensor 700B from he power line. A heavier weight drone may be appropriate for fly-by recovery to prevent the jolt caused by overcoming the spring clamp force when pulling the sensor from the power from overly destabilizing the drone in flight.

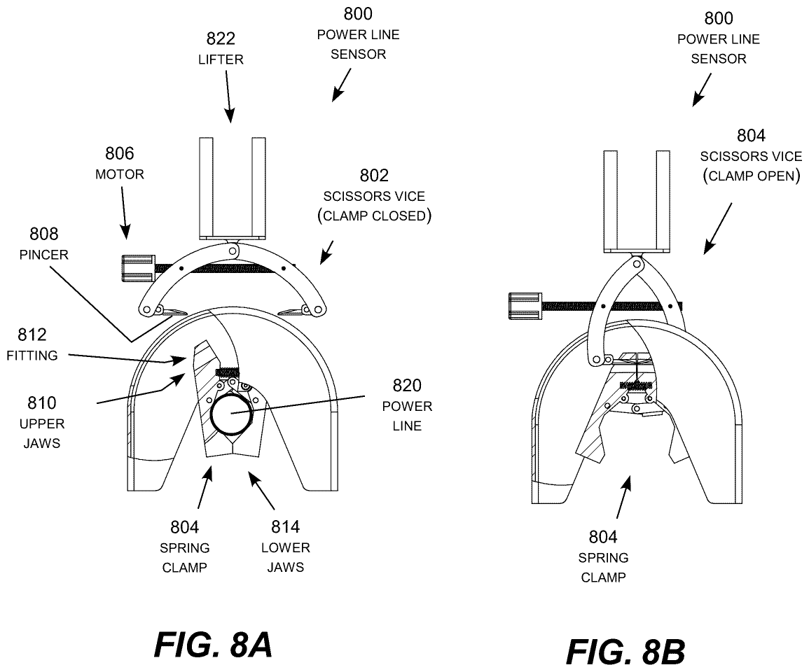

FIGS. 8A and 8B illustrates a sensor 800 an alternative release mechanism, scissors vice 802, utilized by an aerial drone or bucket truck to open the spring clamp 804 to remove the sensor from the power line 820. The assembly includes a remotely controlled motor 806 that operates the scissors vice 802. The scissors vice includes a pair of pincers represented by the enumerated pincer 808. The spring clamp 804 includes an upper jaws 810, half of which is shown in FIG. 8A. The upper jaws includes a pair of fittings represented by the enumerated fitting 812 that received the pincer 808. This provides a stable connection for closing the upper jaws 810, which simultaneously opens the lower jaws 814 to release the sensor 800 from the power line 820. The scissors vice 802 is shown in FIG. 8A the vice open (sensor clamp closed) position, and in FIG. 8B in the vice closed (sensor clamp open) position.

The motor 806 may be controlled by the drone, drone controller (e.g., mobile phone app), local RTU, bucket truck, SCADA control center or another convenient location. A lifter 822 connected to the drone, bucket truck, or other structure lifts the sensor off the power line once the spring clamp 804 has been opened.

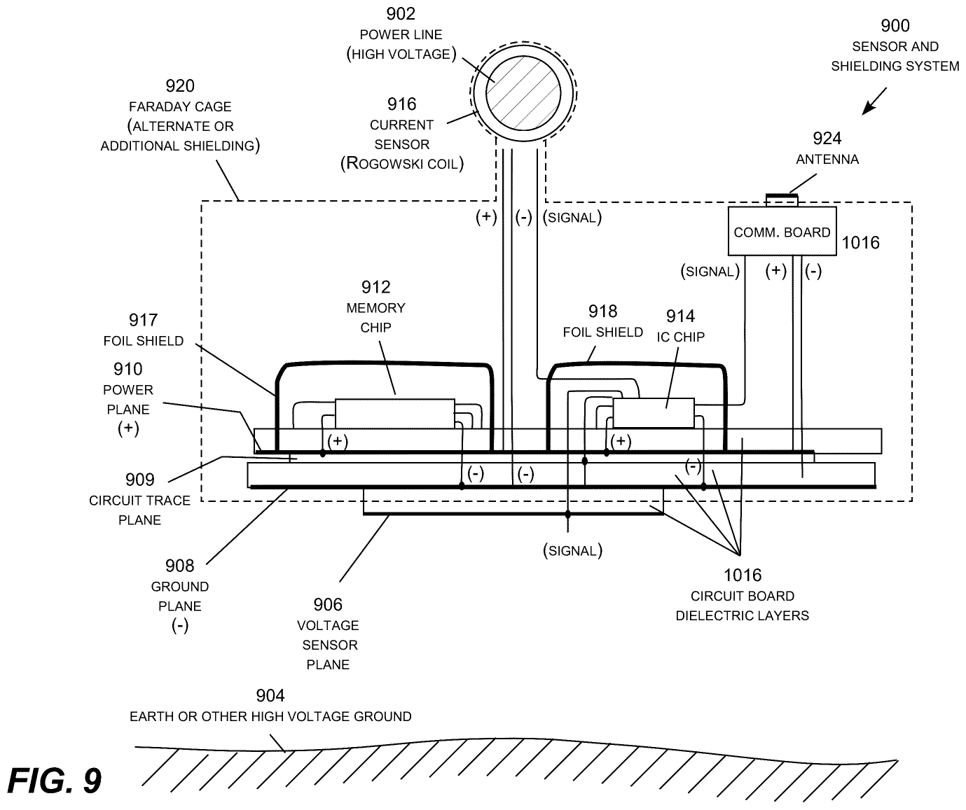

FIG. 9 is a schematic diagram of a sensor and shielding system 900 for the power line sensor, which is spaced apart toward the high voltage ground 904 from a power line 902 in the high-voltage field of the power line. The system includes a printed circuit (PC) board sandwich of metallic planes and dielectric layers beginning with, closest to the earth or other high-voltage, a voltage sensor plane 906 a ground plane 908, a circuit trace plane 909, and a power plane 910. These metal planes are separated by dielectric layers 916 with an additional dielectric layer carrying the chips and other discrete electrical elements on top. The top dielectric layer supports electronic components represented by the memory chip 912 and the integrated circuit (IC) chip 914. A via connect the voltage sensor plane 906 to the IC chip 914 providing a voltage measurement signal to the processor, which is measured with respect to the earth or other high voltage ground 906. The power plane 910 and ground plane 908 are connected by vias to the memory chip 912, the IC chip 914, the current sensor 912 (e.g., Rogowski coil or closed-core CT), and the communications board 916 providing power for these devices. The PC board also supports clam-shell shaped foil shield layers 917 and 918 covering the memory chip 912 and IC chip 914, respectively. An optional faraday cage 920, such as a foil bag, may envelop the PC board and current. The antenna 924 and voltage sensing plane 906 must be outside the Faraday cage 920 to receive the ground signal and exchange communication signals, respectively. Other conventional electronic components (e.g., A/D converter, filter, voltage regulator, lightning arrester, back-up power supplies, back-up antenna, etc.) may also be disposed on the top PC board layer, connected to the components on the top layer of the PC board, or located in other convenient locations.

FIG. 10A is conceptual illustration of a power line sensor 1000 including corona rings 1002a and 1002b disposed adjacent to the bottom of the sensor. The corona rings prevent the relatively sharp corners at the bottom of the housing from generating corona. The corners are also rounded to avoid corona generation at these locations.

FIG. 11A is a front view, FIG. 11B is a top view, and FIG. 11B is a side view of a power line sensor 1100 including a metal, tubular, saddle shaped corona ring 1002 disposed largely on the outer surface of the housing 1104 of the sensor. The corona ring 1102 prevents corona generating from the entire sensor allowing the housing 1104 to be fabricated from an inexpensive non-conductive material, such as polycarbonate or polyester or another suitable plastic material.

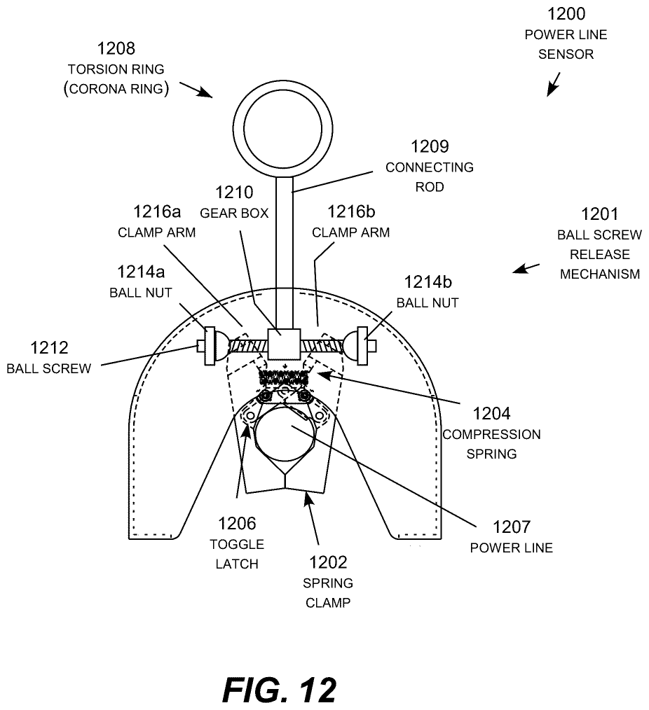

FIG. 12 is a front cut-away view illustrating the ball screw release mechanism 1201 of a representative embodiment of the power line sensor 1200. The sensor 1200 includes a spring clamp 1202, compression spring 1204, and toggle latch 1206 for releasably clamping the sensor 1200 onto a powerline 1207. The release mechanism includes a torsion ring 1208 that serves multiple purposes including serving as an connecting rod for drone installing the sensor, a corona ring, a torsion ring releasing the spring clamp 1202, and optionally a primary or auxiliary antenna for the sensor. In this embodiment, the torsion ring 1208 and connecting rod 1209 remain attached to the sensor 1200 after installation on the power line. The connecting rod 1209 extends from the torsion ring 1208 top a gear box 1210, which provides an adequate gear ration to prevent rotation of the torsion ring by the drone from destabilizing the drone while releasing the clamp. The gear box 1200 rotates a ball screw 1212, which causes ball nuts 1214a and 1214b to translate along the ball screw toward each other, which drives the clamp arms 1216a and 1216b toward each other until the toggle latch 1206 secures the spring clamp 1202 in the open position.

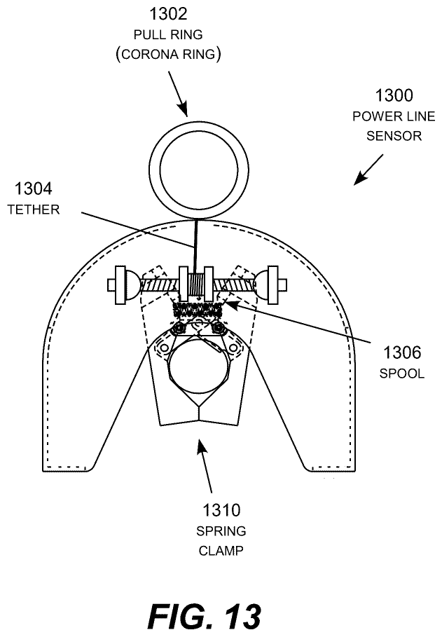

FIG. 13 is a conceptual illustration of a power line sensor 1300 with a different type of release mechanism in which the torsion ring and gear box are replaced by a pull-ring 1302 attached to a tether 1304 wound around a captured spool 1306. A retrieval drone includes a hook that grasps the pull ring 1310, which pulls the pull-ring 1302 to open the spring clamp 1306. Providing a sufficiently long tether 1304 allows a drone to pull the pull ring 1302 to open the spring clam without unduly destabilizing the drone. The pull ring 1302 may alternatively be pulled by a hook stick or other suitable device.

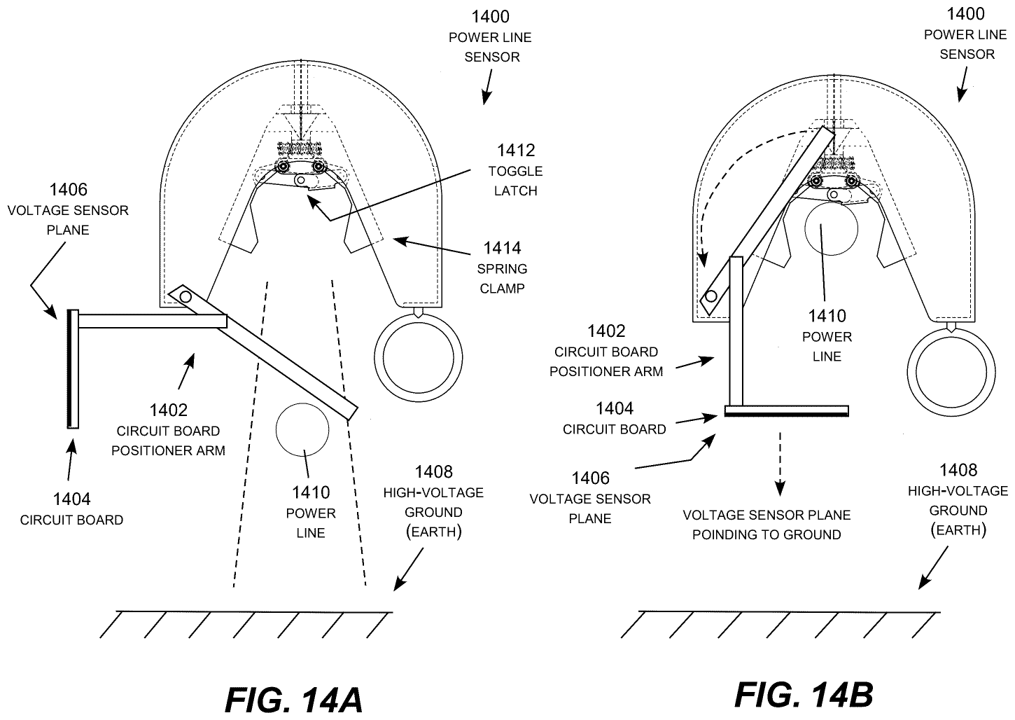

FIGS. 14A and 14B are conceptual illustrations of a power line sensor 1400 with a circuit board positioner arm 1402, which uses the power line to position the circuit board 1404 with the voltage sensor plane 1406 oriented horizontally pointing toward the high voltage ground (Earth) 1408. As shown in FIG. 14A, prior to rotating into position, the positioner arm 1402 is held in a upper position to come into contact with the power line 1410 as the drone lowers the sensor 1400 onto the power line. This rotates the positioner arm 1402 until the power line trips the toggle latch 1412 trips the toggle latch 1412. The positioner is the in a lower position, as shown in FIG. 14B, where the voltage sensor plane 1406 is oriented horizontally pointing toward the high voltage ground (Earth) 1408. The circuit board positioner arm 1402 allows the board to carry a larger voltage sensor plane 1406 compared, for example, to the electronics board 526 shown in FIG. 5, which is positioned within the lower end of an arm of the housing 530. The larger voltage sensor plane 1406 provides for a stronger and more accurate voltage signal.

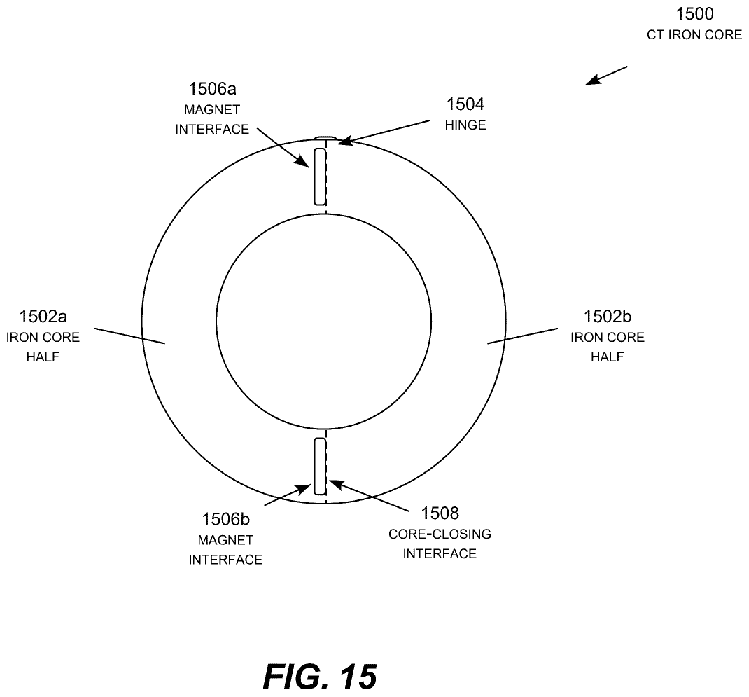

FIG. 15 is a conceptual illustration of split iron core 1500 formed by or integrated into the spring clamp creating a closed core current transformer (CT). The split iron core 1500 includes iron core halves 1502a and 1502b that articulate about a hinge 1504. A pair of weak permanent magnets 1506a and 1506b hold the core closed sufficiently to for a low-resistance magnetic flux path. Unlike a Rogowski coil of other flux coil, the split iron core 1500 can generate hundreds of Watts of power, without the need for a continuous AC power supply other then the power line, enabling the sensor to engage in long-range communications on the order of 10-15 miles or more. A backup battery, capacitor bank or super capacitor may provide communication power even when the power line is deenergized.

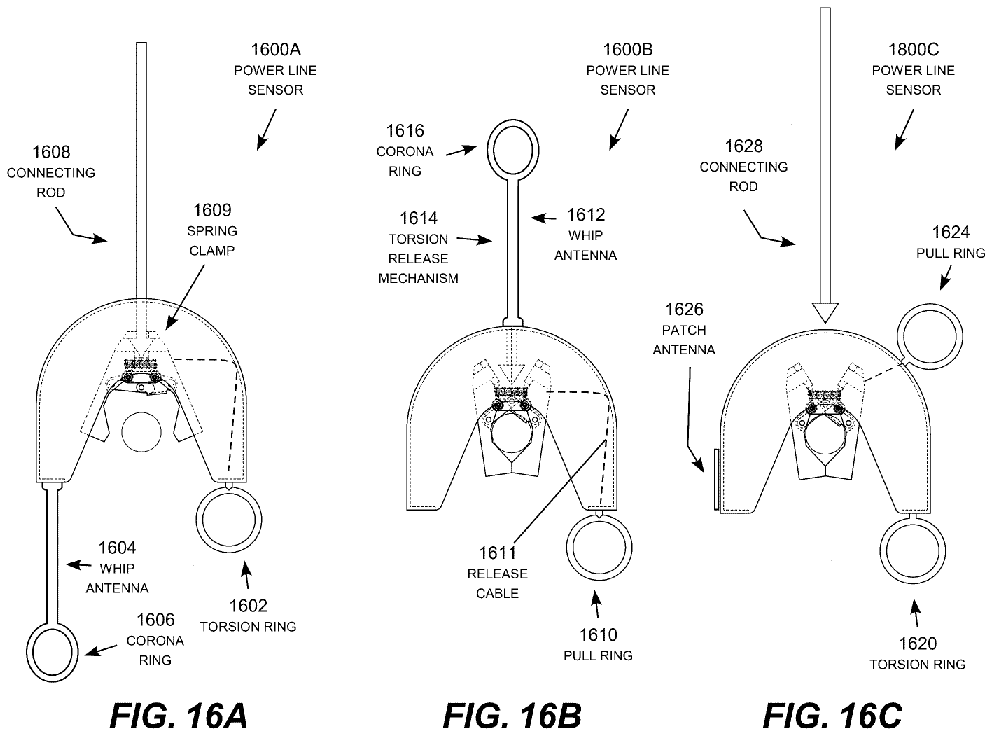

FIGS. 16A-16C illustrate alternative sensors 1600A-1600C with alternative types of release mechanisms and antennas. Each embodiment includes a torsion or pull ring 402 extending from the bottom of one arm of the sensor in addition to another type of release mechanism. Sensor 1600A shown in FIG. 16A includes a torsion ring 1602 extending from the bottom of one arm of the sensor along with a whip antenna 16016 extending from the bottom of the opposing arm. The whip antenna 1606 included a corona ring 1606, which may also serve as a torsion ring, pull ring, or catch ring. In this position, the corona ring 1606 may be grabbed by the drone for fly-by removal of the sensor 1600A from the power line. The version also includes a removable connecting rod 1608.

Power line sensor 1600B shown in FIG. 16B includes a pull ring 1610 extending from the bottom of one arm of the sensor along with a whip antenna 1612 extending from the top of the sensor. The pull ring operates a release cable that is pulled downward to open the spring clamp 1609. The whip antenna 1612 serves multiple functions including serving as a connecting rod triggering the spring clamp when installing the sensor on the power line. Unlike the removable connecting rod 1608, the whip antenna 1612 remains in place after installation of the sensor where it serves as the main antenna or an auxiliary post-EMP antenna. The free end of the of whip antenna 1612 includes a corona ring 1616, which can also serve as a torsion ring or pull ting for removing the sensor from the power line. In this position, the corona ring 1616 may be grabbed by the drone for fly-by removal of the sensor 1600B from the power line.

Power line sensor 1600C shown in FIG. 16C includes a torsion ring 1620 extending from the bottom of one arm of the sensor along with a patch antenna 1622 disposed on the opposing arm. This embodiment also includes a pull ring 16216 positioned level with one the top portion of one of the clamp arms to facilitate the pull release mechanism. The version includes a removable connecting rod 1628.

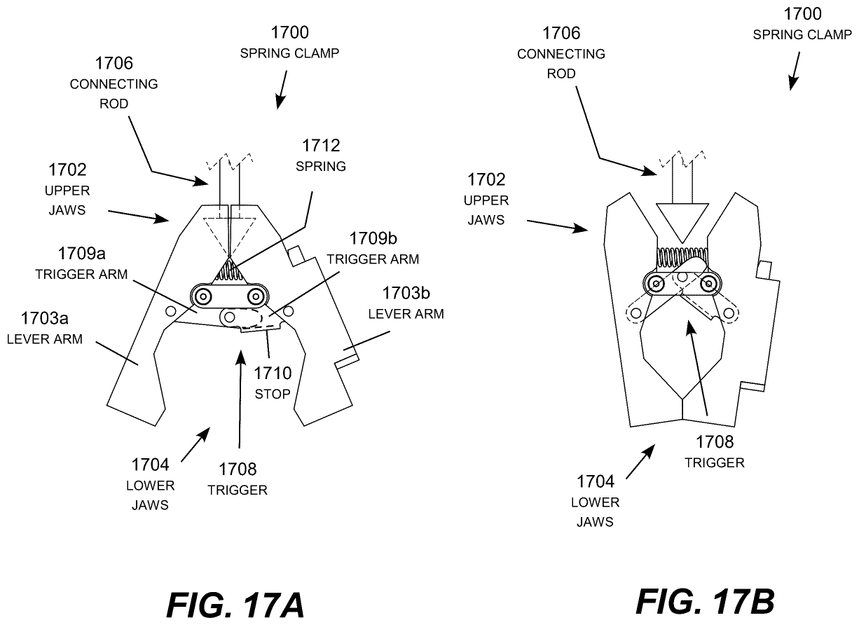

FIGS. 17A-17B are additional conceptual illustrations of a representative spring clamp 1700 illustrating an example trigger 1708. The upper jaws 1702 and lower jaws 1704 are formed by a pair of lever arms 1703a and 1703b pivotally connected to the sensor housing. The trigger 1708 is formed by a pair of trigger arms 1709a and 1709b pivotally connected to the lever arm 1703a and 1703b, respectively. In this example, the trigger arm 1709b includes a stop 1710 that limits the rotation of the trigger arms, thus latching the trigger 1708 in the open position shown in FIG. 17A.

A spring 1712 biases the upper jaws 1702 toward open. To load the spring clamp, the lower jaws 1704 is manually opened until the trigger arms 1709a and 1709b latch, as shown in FIG. 17A. When the aerial drone lowers the sensor until the trigger 1708 comes into contact with the power line, the power line pushes the lever arms 1709a and 1709b upward to release the latch, as shown in FIG. 17B, to simultaneously open the upper jaws 1702 and close the lower jaws 1704. This simultaneously attaches the sensor to the power line and releases the connecting rod 1706 to allow the aerial drone to fly away with the connecting rod. The spring clamp connection mechanism produces the advantage of near instantaneous attachment of the sensor and release of the drone, avoiding the need for the drone to attach to the power line or hover over the installation location for an extended period of time. This greatly simplifies the sensor and reduces the opportunities for mishap during sensor installation.

The foregoing relates only to the exemplary embodiments of the present invention, and numerous changes may be made therein without departing from the spirit and scope of the invention as defined by the following claims.

The invention claimed is:

1. An electric power line sensor, comprising:
a housing;
a spring clamp connection mechanism supported by the housing comprising an upper jaws, a lower jaws, and a trigger;
a connecting rod removably attached to the upper jaws for installing the sensor onto a power line from an aerial drone;
in response to the trigger coming into contact with the power line, the spring clamp simultaneously opening the upper jaws to release the connecting rod and closing the lower jaws to capture the sensor on the power line.

2. The electric power line sensor of claim 1, wherein the lower jaws in a closed forms a current transformer core or positions a Rowgowski coil around the power line.

3. The electric power line sensor of claim 1, further comprising a release mechanism for opening the lower jaws to release the sensor from the power line.

4. The electric power line sensor of claim 1, further comprising two separately operated release mechanisms for opening the lower jaws to release the sensor from the power line.

5. The electric power line sensor of claim 3, wherein the release mechanism comprises a torsion ring.

6. The electric power line sensor of claim 3, wherein the release mechanism comprises a fitting on the upper jaws for receiving a scissors vice operated from the aerial drone.

7. The electric power line sensor of claim 3, wherein the release mechanism comprises a remotely operated electric motor supported by the housing.

8. The electric power line sensor of claim 3, wherein the release mechanism comprises a torsion ring.

9. The electric power line sensor of claim 3, wherein the release mechanism comprises a pull ring.

10. The electric power line sensor of claim 3, wherein the release mechanism comprises a ball screw.

11. The electric power line sensor of claim 3, wherein the release mechanism comprises a tether and a spool.

12. A system for installing a sensor on an electric power line, comprising:
a power line sensor;
a drone for installing the sensor on a power line comprising:
a housing;
a spring clip connection mechanism supported by the housing comprising an upper jaws, a lower jaws, and a trigger;
a connecting rod removably attached to the upper jaws for installing the sensor onto a power line from an aerial drone;
in response to the trigger coming into contact with the power line, the spring clamp simultaneously opening the upper jaws to release the connecting rod and closing the lower jaws to capture the sensor on the power line;
a release mechanism for opening the lower jaws to release the sensor from the power line.

13. The system of claim 12, wherein the lower jaws in a closed forms a current transformer core or positions a Rowgowski coil around the power line.

14. The system of claim 12, further comprising a release mechanism for opening the lower jaws to release the sensor from the power line.

15. The system of claim 14, further comprising two separately operated release mechanisms for opening the lower jaws to release the sensor from the power line.

16. The system of claim 14, wherein the release mechanism comprises a torsion ring.

17. The system of claim 14, wherein the release mechanism comprises a fitting on the upper jaws for receiving a scissors vice operated from the aerial drone.

18. A high voltage sensor system, comprising:
a power line sensor;
a drone for installing the sensor on a power line;
a remote transmission unit (RTU) for relaying power line measurements from the sensor to a remote located control center;
a drone controller remotely controlling the drone during installation of the sensor;
the drone controller receiving the power line measurements from the sensor relayed by the RTU for confirmation of proper operation of the sensor during installation of the sensor;
wherein the power line sensor comprises:
a housing;
a connection mechanism supported by the housing comprising an upper jaws, a lower jaws, and a trigger;
a connecting rod removably attached to the upper jaws for installing the sensor onto a power line from an aerial drone;
in response to the trigger coming into contact with the power line, the spring clamp simultaneously opening the upper jaws to release the connecting rod and closing the lower jaws to capture the sensor on the power line.

19. The system of claim 18, wherein the lower jaws in a closed forms a current transformer core or positions a Rowgowski coil around the power line.

20. The system of claim 18, further comprising a release mechanism for opening the lower jaws to release the sensor from the power line.
